(19) United States
(12) Patent Application Publication
(10) Pub. No.: US 2024/0025669 A1
(43) Pub. Date: Jan. 25, 2024

(54) Method and Apparatus for Gripping Plurality of Types of Circuit Boards

(71) Applicant: Siemens Aktiengesellschaft, München (DE)

(72) Inventors: Yong Wang, Zhuhai (CN); Xi Pan, Chengdu (CN); Bo Gao, Chengdu (CN); Xin Wang, Chengdu (CN); Jian Jun Feng, Dongguan (CN); Jiang Yong Ren, Chengdu (CN)

(73) Assignee: Siemens Aktiengesellschaft, München (DE)

(21) Appl. No.: 18/041,917

(22) PCT Filed: Aug. 17, 2021
(86) PCT No.: PCT/EP2021/072790

§ 371 Date: Feb. 16, 2023

(30) Foreign Application Priority Data
Aug. 17, 2020 (CN) 202010825704.8

(51) Int. Cl. B65G 47/90; H05K 13/00; H05K 3/00

(52) U.S. Cl. CPC B65G 47/90; H05K 13/0069; H05K 3/0052; H05K 2203/1563

(57) ABSTRACT

The present disclosure describes methods and/or apparatus for gripping a plurality of types of circuit boards. For example, a method may include: gripping a first circuit board using a first sub-gripper of an integrated mechanical gripper, wherein the integrated mechanical gripper comprises a plurality of sub-grippers; placing the first circuit board into a transfer platform; gripping the first circuit board from the transfer platform using a second sub-gripper of the plurality of sub-grippers, flipping the first circuit board, and placing the flipped first circuit board into a splitter; splitting the first circuit board into at least one second circuit board with a different type or size from the first circuit board; and gripping the second circuit board from the splitter using a third sub-gripper of the plurality of sub-grippers.

### CROSS-REFERENCE TO RELATED APPLICATIONS

This application is a U.S. National Stage Application of International Application No. PCT/EP2021/072790 filed Aug. 17, 2021, which designates the United States of America, and claims priority to CN Application No. 202010825704.8 filed Aug. 17, 2020, the contents of which are hereby incorporated by reference in their entirety.

### TECHNICAL FIELD

The present disclosure relates to printed circuit boards (PCB). Various embodiments of the teachings herein include methods, integrated mechanical grippers, and/or systems for gripping a plurality of types of circuit boards.

### BACKGROUND

Typically, both loading and unloading of a conventional printed circuit board (PCB) are completed manually during board splitting. However, for a case that there are a plurality of types or sizes of circuit boards, and the circuit boards need to be simultaneously split, a plurality of persons are required to perform operations to separately perform loading and unloading on different types or sizes of PCBs that need to be split. For example, a quantity of persons matching a quantity of types of circuit boards are required to perform operations.

For example, if n (for example, three) circuit boards in one product need to be split, three independent splitter stations or splitters are required. If only one person is assigned to operate a plurality of splitter stations to perform loading and unloading, the person constantly moves back and forth between the plurality of splitter stations for board splitting and assembly. In this way, a production period of the products is greatly increased, and a waiting time is caused. This does not conform to an ergonomics design. However, if three persons are assigned to correspondingly operate three splitters, although the production period is reduced, the utilization of the persons is greatly reduced. Therefore, when loading and unloading need to be simultaneously performed on a plurality of circuit boards during board splitting, the foregoing problems may appear in a convention manual manner. To resolve the problems caused by manual loading and unloading, mechanical grippers are considered to be used in some products to replace a design for manual automatic loading and unloading of the PCB during board splitting of the circuit board. However, for a plurality of different types or sizes of circuit boards (such as complete boards, scrap boards, or single circuit boards), a plurality of robots are still required to respectively grip the circuit boards by using mechanical grippers configured on the robots, which increases costs of the robots.

### SUMMARY

Considering the foregoing problems in the prior art, some embodiments of the teachings of the present disclosure includes methods, integrated mechanical grippers, systems for gripping a plurality of types of circuit boards, and/or computer program products during board splitting of a printed circuit board (PCB).

For example, some embodiments include a method for gripping a plurality of types of circuit boards, comprising: gripping (510) a first circuit board by using a first sub-gripper of an integrated mechanical gripper, wherein the integrated mechanical gripper comprises a plurality of sub-grippers; placing (520) the gripped first circuit board into a transfer platform; gripping the first circuit board from the transfer platform by using a second sub-gripper of the plurality of sub-grippers, flipping the first circuit board, and placing the flipped first circuit board into a splitter (530), to split the first circuit board into at least one second circuit board, wherein the second circuit board has a different type or size from the first circuit board; and gripping (540) the second circuit board from the splitter by using a third sub-gripper of the plurality of sub-grippers.

In some embodiments, the gripping a first circuit board by using a first sub-gripper comprises vertically gripping the first circuit board from at least one first material box by using the first sub-gripper, and the flipping the first circuit board comprises flipping the first circuit board from a vertical placement to a horizontal placement.

In some embodiments, the first circuit board is a complete circuit board, the at least one first material box is capable of respectively storing complete circuit boards of different sizes, each first material box stores at least one complete circuit board of the same size at fixed intervals by using partition boards, and a width between the partition boards is adjustable according to the size of the complete circuit board.

In some embodiments, the at least one first material box is placed at a predetermined position.

In some embodiments, the vertically gripping the first circuit board from at least one first material box by using the first sub-gripper further comprises: guiding the first sub-gripper to a corresponding first material box in a visual guidance manner, to grip the first circuit board, wherein the corresponding first material box stores circuit boards of the same size.

In some embodiments, the method further comprises checking position accuracy of the first circuit board in the splitter by using machine vision when the flipped first circuit board is placed into the splitter, wherein if it is found that the position accuracy of the first circuit board in the splitter is lower than a threshold, a position of the first circuit board in the splitter is adjusted based on the machine vision by using the second sub-gripper.

In some embodiments, the flipped first circuit board is further split into at least one third circuit board in the splitter, the third circuit board has a different type or size from the first circuit board and the second circuit board, and the method further comprises: gripping the third circuit board by using a fourth sub-gripper of the plurality of sub-grippers, to place the third circuit board into a second material box, wherein the fourth sub-gripper is a sub-gripper the same as or different from the second sub-gripper.

In some embodiments, the third circuit board is a scrap circuit board, and the second material box is a scrap material box.

In some embodiments, the second circuit board is a single circuit board, and the method further comprises gripping the single circuit board to a conveying belt at an unloading port by using the third sub-gripper, to convey the single circuit board by using the conveying belt.

In some embodiments, the method further comprises gripping the first circuit board to a scanner for scanning by using the first sub-gripper before the gripped first circuit board is placed into the transfer platform.

As another example, some embodiments include an integrated mechanical gripper (200) for gripping a plurality of types of circuit boards, comprising: a first sub-gripper (202), configured to grip a first circuit board from a first material box and convey the gripped first circuit board to a transfer platform; a second sub-gripper (204), configured to grip the first circuit board from the transfer platform, flip the first circuit board, and place the flipped first circuit board into a splitter, to split the first circuit board into at least one second circuit board, wherein the second circuit board has a different type or size from the first circuit board; and a third sub-gripper (206), configured to grip the second circuit board from the splitter.

In some embodiments, gripping a first circuit board by using a first sub-gripper comprises vertically gripping the first circuit board from at least one first material box by using the first sub-gripper, and flipping the first circuit board comprises flipping the first circuit board from a vertical placement to a horizontal placement.

In some embodiments, the first circuit board is a complete circuit board, the at least one first material box is capable of respectively storing complete circuit boards of different sizes, each first material box stores at least one complete circuit board of the same size at fixed intervals by using partition boards, and a width between the partition boards is adjustable according to the size of the complete circuit board.

In some embodiments, vertically gripping the first circuit board from at least one first material box by using the first sub-gripper further comprises guiding the first sub-gripper to a corresponding first material box in a visual guidance manner, to grip the first circuit board, wherein the corresponding first material box stores circuit boards of the same size.

In some embodiments, the flipped first circuit board is further split into at least one third circuit board in the splitter, the third circuit board has a different type or size from the first circuit board and the second circuit board, and the integrated mechanical gripper further comprises a fourth sub-gripper, configured to grip the third circuit board, to place the third circuit board into a second material box, wherein the third circuit board is a scrap circuit board, the second material box is a scrap material box, and the fourth sub-gripper is a sub-gripper the same as or different from the second sub-gripper.

In some embodiments, the second sub-gripper is further configured to, when the flipped first circuit board is placed into the splitter, if it is found by using machine vision that position accuracy of the first circuit board in the splitter is lower than a threshold, adjust a position of the first circuit board in the splitter based on the machine vision.

In some embodiments, the second circuit board is a single circuit board, and the third sub-gripper is further configured to grip the single circuit board to a conveying belt at an unloading port, to convey the single circuit board by using the conveying belt.

In some embodiments, the first sub-gripper is further configured to grip the first circuit board to a scanner for scanning before the gripped first circuit board is placed into the transfer platform.

As another example, some embodiments include an apparatus for gripping a plurality of types of circuit boards, comprising: at least one processor (610); and a memory (620) coupled to the at least one processor and storing executable instructions, wherein the executable instructions, when being executed by the at least one processor, cause the at least one processor to implement one or more of the methods described herein.

As another example, some embodiments include a system for gripping a plurality of types of circuit boards, comprising: a first material box (104), configured to store a first circuit board; a robot (102) provided with an integrated mechanical gripper, wherein the integrated mechanical gripper is configured to grip, convey, and flip the first circuit board and grip and convey other circuit boards of different types or sizes; a transfer platform (106), configured to store the first circuit board conveyed from the integrated mechanical gripper; and a splitter (110), configured to obtain the flipped first circuit board from the integrated mechanical gripper and split the flipped first circuit board to obtain a second circuit board, wherein the integrated mechanical gripper comprises at least a first sub-gripper, a second sub-gripper, and a third sub-gripper, the first sub-gripper is configured to grip the first circuit board from the first material box and convey the first circuit board to the transfer platform, the second sub-gripper is configured to grip the first circuit board from the transfer platform, flip the first circuit board, and convey the flipped first circuit board to the splitter, and the third sub-gripper is configured to grip the second circuit board from the splitter and convey the second circuit board.

In some embodiments, the system further comprises a scrap material box (114), configured to store a scrap circuit board, wherein the scrap circuit board is obtained by splitting the first circuit board by the splitter, and the integrated mechanical gripper further comprises a fourth sub-gripper, configured to grip the scrap circuit board from the splitter and convey the scrap circuit board to the scrap material box, wherein the fourth sub-gripper is a sub-gripper the same as or different from the second sub-gripper.

In some embodiments, the system further comprises a conveying belt (112), configured to obtain the second circuit board from the third sub-gripper and convey the second circuit board, wherein the second circuit board is a single circuit board.

In some embodiments, the system further comprises a scanner (108), configured to scan the first circuit board before the first circuit board is split.

As another example, some embodiments include a computer program product, wherein the computer program product is tangibly stored on a computer-readable medium and comprises computer-executable instructions, and the computer-executable instructions, when being executed, cause at least one processor to perform one or more of the methods described herein.

### BRIEF DESCRIPTION OF THE DRAWINGS

The following description and the accompanying drawings describe some illustrative features in detail of the teachings herein. The features merely indicate a plurality of manner in which principles in various aspects can be implemented, and content of the present disclosure is intended to include all the aspects and equivalents. The foregoing characteristics, technical features, advantages and implementations of the teachings of the present disclosure are further described below in a clear and easy-to-understand manner by describing example embodiments and with reference to the accompanying drawings. In the drawings:

FIG. 1 schematically shows an automatic loading and unloading system incorporating teachings of the present disclosure in which an integrated mechanical gripper is used during board splitting of a printed circuit board (PCB);

FIG. 2 is a schematic diagram of an exemplary robot having an integrated mechanical gripper incorporating teachings of the present disclosure;

FIG. 3 is an exemplary complete material box configured to store a complete circuit board incorporating teachings of the present disclosure;

FIG. 4 is a schematic flowchart of a method for splitting a plurality of types of circuit boards incorporating teachings of the present disclosure;

FIG. 5 is a schematic flowchart of a method for gripping a plurality of types of circuit boards incorporating teachings of the present disclosure; and

FIG. 6 is a schematic block diagram of an apparatus for gripping a plurality of types of circuit boards incorporating teachings of the present disclosure.

### LIST OF REFERENCE NUMERALS

100: system;
102: robot;
104: complete material box;
106: transfer platform;
108: scanner;
110: splitter;
112: conveying belt;
114: scrap material box;
200: integrated mechanical gripper;
202: sub-gripper 1;
204: sub-gripper 2;
206: sub-gripper 3;
300: complete material box;
302 to 308: partition boards;
400: method;
402: gripping a complete circuit board;
404: gripping the complete circuit board to a scanner for scanning;
406: whether the scanning succeeds;
408: placing the complete circuit board into a transfer platform;
410: issuing an alarm or placing the complete circuit board into a spare material box;
412: placing a flipped complete circuit board into a splitter;
414: whether position accuracy of the complete circuit board in the splitter is higher than a threshold;
416: adjusting a position of the complete circuit board in the splitter by using machine vision;
418: splitting the complete circuit board;
420: conveying a single board obtained through board splitting to a conveying belt;
422: placing a scrap board obtained through board splitting into a scrap material box;
500: method;
510: gripping a first circuit board by using a first sub-gripper of an integrated mechanical gripper;
520: placing the gripped first circuit board into a transfer platform;
530: gripping the first circuit board by using a second sub-gripper, flipping the first circuit board, and placing the flipped first circuit board into a splitter, to split the first circuit board into at least one second circuit board;
540: gripping a second circuit board from the splitter by using a third sub-gripper;
600: apparatus;
610: processor; and
620: memory.

### DETAILED DESCRIPTION

To reduce costs of labors or robots, the teachings of the present disclosure include highly integrated designs for the same mechanical gripper assembled on a robot, so that the mechanical gripper has a plurality of sub-grippers capable of respectively gripping a plurality of different types or sizes of circuit boards (for example, complete boards, scrap boards, or single circuit boards). That is, the integrated mechanical gripper integrates a plurality of adjustable sub-grippers with different functions to be suitable for the plurality of different types or sizes of circuit boards.

In some embodiments, a method for gripping a plurality of types of circuit boards includes: gripping a first circuit board by using a first sub-gripper of an integrated mechanical gripper, where the integrated mechanical gripper includes a plurality of sub-grippers; placing the gripped first circuit board into a transfer platform; gripping the first circuit board from the transfer platform by using a second sub-gripper of the plurality of sub-grippers, flipping the first circuit board, and placing the flipped first circuit board into a splitter, to split the first circuit board into at least one second circuit board, where the second circuit board has a different type or size from the first circuit board; and gripping the second circuit board from the splitter by using a third sub-gripper of the plurality of sub-grippers. During board splitting of the PCB, the plurality of different types or sizes of circuit boards may be gripped by using only the same mechanical gripper integrated with the plurality of sub-grippers. Because the same mechanical gripper integrated with the plurality of sub-grippers only needs to be disposed on one robot, this reduces the costs of labors or robots. Further, because the mechanical gripper may be suitable for the plurality of types or sizes of circuit boards, there is no need to change or redesign the mechanical gripper even if a circuit board design of a product is changed.

In some embodiments, gripping a first circuit board by using a first sub-gripper includes vertically gripping the first circuit board from at least one first material box by using the first sub-gripper, and flipping the first circuit board includes flipping the first circuit board from a vertical placement to a horizontal placement. Because the circuit board is generally vertically placed in the material box to facilitate being gripped, and the circuit board is generally horizontally placed on a splitter platform to facilitate being split, the circuit board may be more easily and accurately placed on the splitter platform by adjusting a posture of the circuit board during loading.

In some embodiments, the first circuit board is a complete circuit board (also referred to as a “complete board” in this specification), the at least one first material box is capable of respectively storing complete circuit boards of different sizes, each first material box stores at least one complete circuit board of the same size at fixed intervals by using partition boards, and a width between the partition boards is adjustable according to the size of the complete circuit board.

In some embodiments, the at least one first material box is placed at a predetermined position.

In some embodiments, vertically gripping the first circuit board from at least one first material box by using the first sub-gripper further includes: guiding the first sub-gripper to a corresponding first material box in a visual guidance manner, to grip the first circuit board, where the corresponding first material box stores circuit boards of the same size.

In some embodiments, the method further includes: checking position accuracy of the first circuit board in the splitter by using machine vision when the flipped first circuit board is placed into the splitter, where if it is found that the position accuracy of the first circuit board in the splitter is lower than a threshold, a position of the first circuit board in the splitter is adjusted based on the machine vision by using the second sub-gripper. An accurate placement of the complete circuit board in the splitter platform or a splitter fixture is ensured by using the machine vision before board splitting, thereby preventing the circuit board from being damaged due to an inaccurate position during board splitting.

In some embodiments, the flipped first circuit board is further split into at least one third circuit board in the splitter, the third circuit board has a different type or size from the first circuit board and the second circuit board, and the method further includes: gripping the third circuit board by using a fourth sub-gripper in the plurality of sub-grippers, to place the third circuit board into a second material box, where the fourth sub-gripper is a sub-gripper the same as or different from the second sub-gripper.

In some embodiments, the third circuit board is a scrap circuit board (also referred to as a “scrap board” in this specification), and the second material box is a scrap material box. During the same board splitting, different types or sizes of circuit boards may be gripped by using different sub-grippers of the same mechanical gripper, thereby reducing a quantity of required mechanical grippers and robots.

In some embodiments, the second circuit board is a single circuit board (also referred to as a “single board” in this specification). The method further includes: gripping the single circuit board to a conveying belt at an unloading port by using the third sub-gripper, to convey the single circuit board by using the conveying belt. During the same board splitting, different types or sizes of circuit boards may be gripped by using different sub-grippers of the same mechanical gripper, thereby reducing a quantity of required mechanical grippers and robots.

In some embodiments, the method further includes gripping the first circuit board to a scanner for scanning by using the first sub-gripper before the gripped first circuit board is placed into the transfer platform. A circuit board with problems may be detected when the circuit board is scanned before being transferred, so as to immediately interrupt the board splitting process and avoid splitting the wrong circuit board, thereby saving time and reducing a board scrap rate.

In some embodiments, an integrated mechanical gripper for gripping a plurality of types of circuit boards includes: a first sub-gripper, configured to grip a first circuit board from a first material box and convey the gripped first circuit board to a transfer platform; a second sub-gripper, configured to grip the first circuit board from the transfer platform, flip the first circuit board, and place the flipped first circuit board into a splitter, to split the first circuit board into at least one second circuit board, where the second circuit board has a different type or size from the first circuit board; and a third sub-gripper, configured to grip the second circuit board from the splitter.

In some embodiments, gripping a first circuit board by using a first sub-gripper includes vertically gripping the first circuit board from at least one first material box by using the first sub-gripper, and the flipping the first circuit board includes flipping the first circuit board from a vertical placement to a horizontal placement.

In some embodiments, the first circuit board is a complete circuit board, the at least one first material box is capable of respectively storing complete circuit boards of different sizes, each first material box stores at least one complete circuit board of the same size at fixed intervals by using partition boards, and a width between the partition boards is adjustable according to the size of the complete circuit board.

In some embodiments, vertically gripping the first circuit board from at least one first material box by using the first sub-gripper further includes guiding the first sub-gripper to a corresponding first material box in a visual guidance manner, to grip the first circuit board, where the corresponding first material box stores circuit boards of the same size.

In some embodiments, the flipped first circuit board is further split into at least one third circuit board in the splitter, the third circuit board has a different type or size from the first circuit board and the second circuit board, and the integrated mechanical gripper further includes: a fourth sub-gripper, configured to grip the third circuit board, to place the third circuit board into a second material box, where the third circuit board is a scrap circuit board, the second material box is a scrap material box, and the fourth sub-gripper is a sub-gripper the same as or different from the second sub-gripper.

In some embodiments, the second sub-gripper is further configured to, when the flipped first circuit board is placed into the splitter, if it is found by using machine vision that position accuracy of the first circuit board in the splitter is lower than a threshold, adjust a position of the first circuit board in the splitter based on the machine vision.

In some embodiments, the second circuit board is a single circuit board, and the third sub-gripper is further configured to grip the single circuit board to a conveying belt at an unloading port, to convey the single circuit board by using the conveying belt.

In some embodiments, the first sub-gripper is further configured to grip the first circuit board to a scanner for scanning before the gripped first circuit board is placed into the transfer platform.

In some embodiments, an apparatus for gripping a plurality of types of circuit boards includes: at least one processor; and a memory coupled to the at least one processor and storing executable instructions, where the executable instructions, when being executed by the at least one processor, implement one or more of the methods described herein.

In some embodiments, a system for gripping a plurality of types of circuit boards includes: a first material box, configured to store a first circuit board; an integrated mechanical gripper, configured to grip, convey, and flip the first circuit board and grip and convey other circuit boards of different types or sizes; a transfer platform, configured to store the first circuit board conveyed from the integrated mechanical gripper; and a splitter, configured to obtain the flipped first circuit board from the integrated mechanical gripper and split the flipped first circuit board to obtain a second circuit board, where the integrated mechanical gripper includes at least a first sub-gripper, a second sub-gripper, and a third sub-gripper, the first sub-gripper is configured to grip the first circuit board from the first material box and convey the first circuit board to the transfer platform, the second sub-gripper is configured to grip the first circuit board from the transfer platform, flip the first circuit board, and convey the flipped first circuit board to the splitter, and the third sub-gripper is configured to grip the second circuit board from the splitter and convey the second circuit board.

In some embodiments, a computer program product is tangibly stored on a computer-readable medium and includes computer-executable instructions, and the computer-executable instructions, when being executed, cause at least one processor to perform one or more of the methods described herein.

The integrated mechanical grippers described in the present disclosure resolves the problem of simultaneous loading and unloading of the plurality of types or sizes of circuit boards, and potential benefits are as follows:
1. Reduce investment of persons and robots;
2. Provide a high level of quality control, where the precision of the complete circuit board in the splitter or the splitter fixture is ensured by using the machine vision, thereby preventing the circuit board from being damaged due to an inaccurate position during board splitting; and/or
3. A flexible design makes the integrated mechanical gripper suitable for more types or sizes of circuit boards, and therefore there is no need to change the integrated mechanical gripper if a circuit board design of a product is changed.

A printed circuit board (PCB) is one of important components in the electronic industry and a carrier for electrically connecting an electronic element. In an assembly process of the PCB, a complete circuit board generally needs to be split to obtain a single circuit board. The present disclosure includes technology for gripping a plurality of different types of circuit boards by using an integrated mechanical gripper during board splitting of the PCB and performing loading and unloading.

The content of the present disclosure is now discussed with reference to a plurality of exemplary embodiments. It should be understood that the discussion of the embodiments is merely used to enable a person skilled in the art to better understand and thus implement the embodiments in the content of the present disclosure, and does not teach any limitation on the scope of the content of the present disclosure.

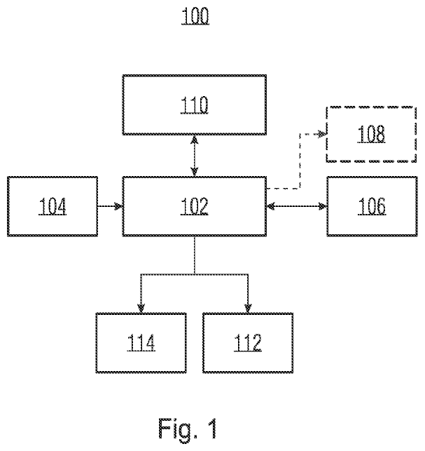

FIG. 1 shows an automatic loading and unloading system 100 in which an integrated mechanical gripper is used during board splitting of a PCB incorporating teachings of the present disclosure. As shown in FIG. 1, the automatic loading and unloading system 100 may include a robot 102, a complete material box 104, a transfer platform 106, a scanner 108, a splitter or a splitter platform 110, a conveying belt 112, and a scrap material box 114.

The robot 102 Ides a body anI an integrated mechanical gripper disposed on the body. The mechanical gripper includes a plurality of sub-grippers, configured to grip and/or convey circuit boards of different types or sizes. In some embodiments, the robot 102 may be a six-axis robot. As shown, the robot 102 obtains a complete circuit board from the complete material box 104 by using a sub-gripper (for example, a first sub-gripper) in the integrated mechanical gripper, for example, vertically takes out the complete circuit board from the complete material box.

A plurality of complete material boxes 104 may respectively store complete circuit boards of different types or sizes, and each material box 104 is configured to store one or more complete circuit boards of the same type or size. In some examples, when the integrated mechanical gripper needs to grip a complete circuit board of a specific type or size, the integrated mechanical gripper may be guided, in a visual guidance manner by using a camera, to a corresponding material box to grip the complete circuit board of the specific type or size. In some embodiments, the camera may be placed on the robot, for example, placed on a front end of the integrated mechanical gripper. In some other embodiments, the camera may be placed outside the robot, for example, placed on an upper end of the material box. In some other examples, the corresponding material box configured to store the circuit board of the specific size or type may be placed at a predetermined position, so that the integrated mechanical gripper may grip a circuit board of a required type or size.

After obtaining the complete circuit board from the complete material box 104, the robot 102 may convey the complete circuit board to the transfer platform 106. In some embodiments, before conveying the complete circuit board to the transfer platform 106, the robot 102 may convey the complete circuit board to the scanner 108. The scanner 108 scans the complete circuit board, to further determine a type of the complete board or validity or provide related information of the complete board. For example, the scanner 108 may provide a type or size of the complete board to the robot 102 by scanning the complete board, so that the robot 102 determines whether the type or size of the complete board matches a type or size of a complete board to be gripped.

In some embodiments, the scanner 108 may scan the complete circuit board to recognize whether the circuit board passes a quality test. If the scanner 108 recognizes, by scanning information of the complete circuit board, that the circuit board fails in the quality test or the type or size of the complete circuit board does not conform to the type or size of the circuit board that intends to be gripped this time, the scanner 108 may notify an operator or the robot 102 to reprocess the complete circuit board, for example, place the complete circuit board into a scrap material box to discard the circuit board or place the complete circuit board into a spare material box for subsequent processing.

In some embodiments, the robot 102 obtains the complete circuit board from the transfer platform by using another sub-gripper (for example, a second sub-gripper) in the integrated mechanical gripper, and flips the complete circuit board, for example, switches the complete circuit board from a vertical placement to a horizontal placement. The robot 102 conveys the flipped complete circuit board to the splitter 110 by using another sub-gripper, so that the splitter 110 splits the complete circuit board. In some examples, the robot 102 grips, by using a different still another sub-gripper (for example, a third sub-gripper), a single circuit board obtained through board splitting from the splitter 110, and conveys the single circuit board to the conveying belt 112 at an unloading port, so that the single circuit boards are gathered and conveyed for assembly.

In some embodiments, the robot 102 may grip a scrap board after board splitting by using a fourth sub-gripper, and convey or discard the scrap board to the scrap material box 114. In some embodiments, the fourth sub-gripper may be a sub-gripper the same as or different from the second sub-gripper. In addition, in some embodiments, the complete circuit board used for board splitting, the single circuit board obtained after board splitting, and the scrap circuit board may be all of different types or sizes, or may be of the same size in one or both (for example, the same width of the complete circuit board or the scrap circuit board). The components shown in FIG. 1 are merely exemplary. In actual application, one or more components may be increased or decreased according to requirements.

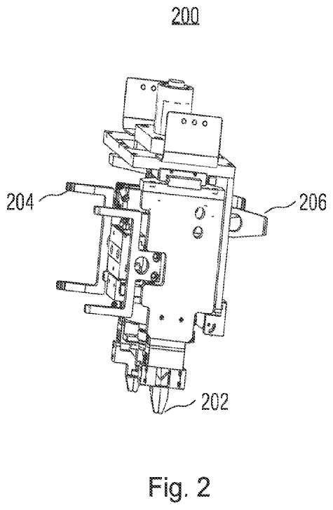

FIG. 2 is a schematic diagram of an exemplary integrated mechanical gripper 200 incorporating teachings of the present disclosure. It should be understood that although the integrated mechanical gripper is not shown in FIG. 2, the integrated mechanical gripper 200 may be disposed on a robot (for example, the robot 102 shown in FIG. 1), for example, mounted on a body or a base of the robot.

As shown in FIG. 2, the integrated mechanical gripper 200 is integrated with a plurality of sub-grippers such as a first sub-gripper 202, a second sub-gripper 204, and a third sub-gripper 206 shown in FIG. 2. Although only three sub-grippers are shown in the figure, the integrated mechanical gripper 200 may be configured to have more or less than three sub-grippers according to practical requirements.

In some embodiments, the first sub-gripper 202 is configured to grip a complete circuit board from a complete material box, for example, vertically grip the complete circuit board. In some examples, the first sub-gripper 202 is of an adjustable clamp-type design, is configured to grip a board edge of the complete circuit board, and may grip the complete circuit boards of different sizes, for example, PCBs with board edge widths of 100 mm to 300 mm. This is not limited in the present invention.

In some embodiments, the second sub-gripper 204 is configured to grip the complete circuit board from a transfer platform. In some examples, the second sub-gripper 204 clamps the complete circuit board by using four chucks, flips the complete circuit board, and conveys the complete circuit board to a splitter. The complete circuit board may be flipped from a vertical direction to a horizontal direction. Although the complete circuit board obtained from the transfer platform is flipped by using the second sub-gripper in this example, in practice, the complete circuit board may be alternatively flipped at the transfer platform, so that the second sub-gripper grips the flipped circuit board from only the transfer platform and does not flip the circuit board.

In some embodiments, the second sub-gripper 204 may grip a scrap board obtained through board splitting from the splitter. In some examples, the second sub-gripper 204 grips a frame of the scrap board and conveys or discards the scrap board to a scrap material box. The second sub-gripper is of a flexible design, and may be configured to grip circuit boards of different sizes, for example, PCBs with board edge widths of 120 mm to 170 mm. It should be understood that although the scrap board is gripped and conveyed by using the second sub-gripper in this example, the scrap board may be alternatively gripped from the splitter by using another sub-gripper (for example, a fourth sub-gripper not shown in the figure) different from the second sub-gripper and conveyed to the scrap material box in another example.

In some embodiments, the third sub-gripper 206 is configured to grip a single circuit board obtained through board splitting from the splitter and convey the single circuit board to at least one conveying belt at an unloading port, so that the single board is conveyed for subsequent assembly and use. In some examples, the third sub-gripper is of the flexible design, and may be configured to grip circuit boards of different sizes. For example, the third sub-gripper clamps or grips a single PCB in a width direction by using two chucks, and may clamp single circuit boards with clampable widths of 60 mm to 80 mm. This is not limited in the present invention.

In some embodiments, a camera may be mounted on the integrated mechanical gripper 200 or a robot on which the integrated mechanical gripper is located. In some embodiments, when the first sub-gripper intends to grip the complete circuit board from the complete material box, the camera may be configured to guide the first sub-gripper to a corresponding complete material box in a visual guidance manner. In some embodiments, when the second sub-gripper places the flipped complete circuit board into the splitter, the camera may be configured to check position accuracy of the complete circuit board in the splitter by using machine vision.

For example, if it is found that a position of the complete circuit board in the splitter is incorrect, for example, the position accuracy is lower than a threshold, a prompt or alarm may be issued to the robot or an operator, to instruct the second sub-gripper to adjust the position of the complete board in the splitter based on the machine vision (for example, a guidance of the camera), thereby ensuring the position accuracy of the complete board in the splitter or a splitter fixture and preventing the circuit board from being damaged due to an inaccurate position during board splitting. In some other examples, the camera may be further configured to guide, in a visual guidance manner, the third sub-gripper to accurately convey the single board obtained after board splitting to the conveying belt, and guide the second sub-gripper to accurately place the scrap board obtained after board splitting into the scrap material box. Although the camera is set to be a single camera mounted on the integrated mechanical gripper 200 or the robot having the integrated mechanical gripper in this embodiment, in practice, the camera may be set to be one or more cameras mounted outside the integrated mechanical gripper 200, such as cameras respectively mounted on an upper end of or near the complete material box, and/or cameras mounted on an upper end of or near the splitter, and/or cameras mounted on the conveying belt or near the scrap material box.

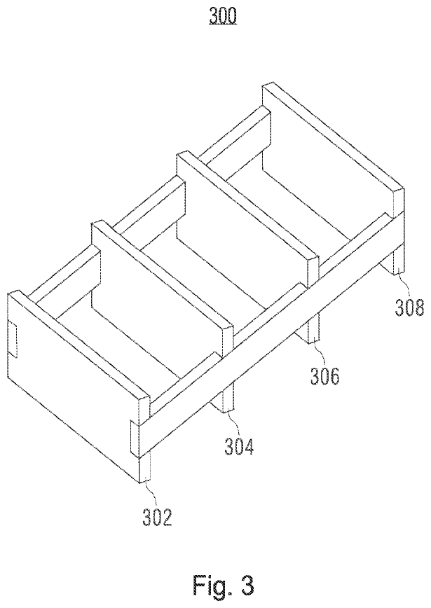

FIG. 3 is an exemplary complete material box 300 configured to store a complete circuit board incorporating teachings of the present disclosure. In this embodiment, the complete material box 300 may be a standard-shaped box configured to store or place the complete PCB. Different complete material boxes may be respectively configured to store complete circuit boards of same or different sizes, and each complete material box may store a plurality of circuit boards of the same size. In an example, a first complete material box may store a plurality of circuit boards of a first size, a second complete material box may store a plurality of circuit boards of a second size, and so on.

In some embodiments, the first complete material box may store a plurality of circuit boards of a first size, the second complete material box may store the plurality of circuit boards of the first size, a third complete material box may store a plurality of circuit boards of a second size, and so on. In an example, in a loading area, each complete material box may be placed at a predetermined position. In another example, the complete material box may be randomly placed at any position in the loading area.

A dedicated partition board with an adjustable width may be designed in the complete material box 300. A spacing between the partition boards in the same material box configured to store at least one circuit board of the same type or size may be fixed, so that a fixed spacing is kept between a plurality of complete boards, for example, partition boards 302, 304, 306, and 308 shown in FIG. 3, stored in a complete material box. In some examples, widths between the partition boards may be adjusted according to different sizes or widths of the complete boards to be stored in the complete material box 300, to be suitable for storing a plurality of types of PCB complete boards of different sizes. The partition boards disposed in the complete material box 300 may cause a plurality of complete circuit boards stored in the complete material box to have a specific distance, thereby preventing the circuit boards from being damaged because the plurality of circuit boards are squeezed together. In addition, the fixed spacing between a plurality of partition boards in the complete material box may cause the integrated mechanical gripper to more accurately position each circuit board when gripping the complete circuit boards from the material box. Although four partition boards are shown in the complete material box 300 in FIG. 3, in practice, any quantity of partition boards may be set according to requirements to store a plurality of PCB complete boards.

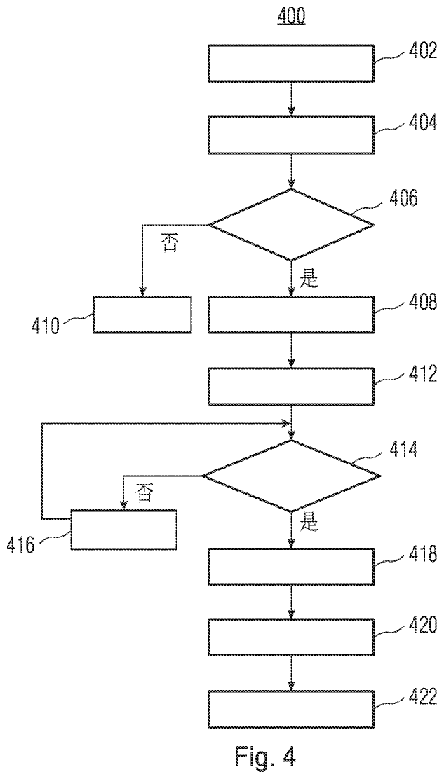

FIG. 4 is a schematic flowchart of a method 400 for splitting a plurality of types of circuit boards incorporating teachings of the present disclosure. The method 400 may be performed by the system 100 in FIG. 1.

In step 402, an integrated mechanical gripper may grip a complete circuit board from a complete material box. In this embodiment, the integrated mechanical gripper is mounted on a body of a robot and includes at least one sub-gripper. In an example, a first sub-gripper in the integrated mechanical gripper may vertically grip a complete circuit board of a required type or size from the complete material box.

In an optional step 404, the first sub-gripper may grip the complete circuit board to a scanner for scanning, to detect or determine whether the gripped complete board has problems, such as whether the gripped complete board passes a quality test or whether the gripped complete board is a complete board of a required type or size. The scanner in this embodiment may be a three-dimensional (3D) laser scanner, or any another suitable scanner in the art.

In an optional step 406, whether the complete circuit board passes the scanning by the scanner is determined. For example, if the gripped complete board meets requirements and is the required complete circuit board, it is considered that the complete circuit board passes the scanning by the scanner, and step 408 is performed. If the gripped complete board is not the complete board of the required type or size, or is not subject to the quality test, it is considered that the complete circuit board fails in the scanning by the scanner, and step 410 is performed.

In step 408, the first sub-gripper places the complete circuit board that passes the scanning into a transfer platform. In an example, the transfer platform may be configured to store only the circuit board. In another example, the transfer platform may be configured to store the circuit board and flip the circuit board, for example, flip the circuit board from a vertical placement to a horizontal placement or flip the circuit board from a horizontal placement to a vertical placement.

In step 410, when the complete circuit board fails in the scanning by the scanner, the scanner may issue an alarm, for example, issue an indication to an operator or the robot by using an alarm signal such as sound, flashing, or red light to indicate that the current complete board does not meet requirements or has problems, and is unable to be split, so as to notify the operator or the robot to process the complete board, such as return for rescanning, re-perform the quality test, or discard the complete board. In some embodiments, when the complete circuit board fails in the scanning by the scanner, the integrated mechanical gripper may place the complete circuit board into a spare material box. In some examples, the integrated mechanical gripper may return to the complete material box and re-grip the complete circuit board to continue this process, or the integrated mechanical gripper may wait for a further indication of the operator.

In step 412, a flipped complete circuit board is placed into a splitter. In some embodiments, if the complete circuit board is not flipped at the transfer platform in step 408, in step 412, the complete circuit board may be gripped from the transfer platform by using a second sub-gripper in the integrated mechanical gripper, the complete circuit board is flipped (for example, flipped from a vertical placement to a horizontal placement), and the flipped complete circuit board is placed into the splitter. In some embodiments, if the complete circuit board has been flipped at the transfer platform in step 408, in step 412, the second sub-gripper grips the flipped circuit board from the transfer platform and directly conveys the circuit board to the splitter without performing further flipping again.

In some embodiments, in step 414, whether a position of the complete circuit board in the splitter is accurate may be determined. For example, execution is performed by determining whether position accuracy of the complete circuit board in the splitter is higher than a threshold. In an example, determination may be performed by comparing a matching degree or fit between four corners of the complete circuit board and four corners in the splitter. The determination method is not limited in the present invention.

If the determination in step 414 is “No”, that is, the position of the complete circuit board in the splitter is inaccurate, step 416 is performed. In step 416, the position of the complete board in the splitter is adjusted by, for example, the second sub-gripper in the integrated mechanical gripper by using a camera based on machine vision. After the position of the complete board in the splitter is adjusted, step 414 may be returned again, to re-determine whether the adjusted position of the complete board is accurate. The determining operation in step 414 and the adjustment operation in step 416 may be repeatedly performed once or for a plurality of times until it is determined that the position of the complete board in the splitter is accurate or the position accuracy is higher than the threshold.

If the determination in step 414 is “Yes”, that is, the position of the complete circuit board in the splitter is accurate, step 418 is performed. In step 418, the complete circuit board is split by using the splitter.

In step 420, a single board obtained through board splitting is conveyed to a conveying belt at an unloading port, to further convey the single board to an assembly component to assemble the single board. In an embodiment, the single board may be gripped from the splitter by using a third sub-gripper in the integrated mechanical gripper and conveyed.

In some embodiments, in step 422, a scrap board obtained through board splitting may be placed into a scrap material box. In some embodiments, the scrap board may be gripped from the splitter by using the second sub-gripper or an another different sub-gripper (for example, a fourth sub-gripper) in the integrated mechanical gripper and conveyed.

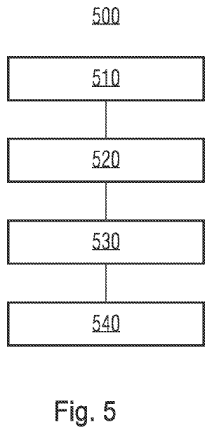

FIG. 5 is a schematic flowchart of a method 500 for gripping a plurality of types of circuit boards incorporating teachings of the present disclosure.

In a block 510, a first circuit board may be gripped by using a first sub-gripper of an integrated mechanical gripper. In an embodiment, the first circuit board is a complete circuit board. In this embodiment, at least one complete board may be gripped from at least one complete material box by using the first sub-gripper. For example, the complete board is vertically gripped from a complete material box. In some examples, the integrated mechanical gripper may be mounted on a body of a robot and includes a plurality of sub-grippers.

In a block 520, the gripped first circuit board may be placed into a transfer platform by using the first sub-gripper.

In a block 530, the first circuit board may be gripped from the transfer platform by using a second sub-gripper in the integrated mechanical gripper, the first circuit board is flipped, and the flipped first circuit board is placed into a splitter, to split the first circuit board into at least one second circuit board (for example, single boards). In an example, the second circuit board is a single board, and has a different type or size from the first circuit board (for example, the complete board). In some examples, the flipping the complete board includes flipping the complete board from a vertical placement to a horizontal placement. In some embodiments, the operation of flipping the complete board may be performed at the transfer platform.

In a block 540, the second circuit board may be gripped from the splitter by using a third sub-gripper in the integrated mechanical gripper. In some examples, the third sub-gripper may convey the gripped second circuit board (for example, the single board) to a conveying belt at an unloading port, to convey the single circuit boards by using the conveying belt.

In some embodiments, the at least one complete material box may respectively store complete boards of different sizes. Further, in these embodiments, each complete material box may store at least one complete circuit board of the same size at fixed intervals by using partition boards, and a width between the partition boards is adjustable according to the size of the complete circuit board.

In some embodiments, the complete material box may be placed at a predetermined position.

In some embodiments, the first sub-gripper may be guided to a corresponding complete material box in a visual guidance manner, to grip the complete circuit board, where the corresponding complete material box stores circuit boards of the same size.

In some embodiments, the method 500 further includes: checking position accuracy of the complete circuit board in the splitter by using machine vision when the flipped complete circuit board is placed into the splitter, where if it is found that the position accuracy of the complete circuit board in the splitter is lower than a threshold, a position of the complete circuit board in the splitter is adjusted based on the machine vision by using the second sub-gripper.

In some embodiments, the flipped complete circuit board is further split into scrap boards in the splitter, where the scrap board has a different type or size from the complete board and the single board, and the method further includes: gripping the scrap board by using a fourth sub-gripper in the integrated mechanical gripper, to place the scrap board into a scrap material box. In some examples, the fourth sub-gripper may be a sub-gripper the same as or different from the second sub-gripper.

In some embodiments, before the gripped complete circuit board is placed into the transfer platform, the complete circuit board is gripped to a scanner for scanning by using the first sub-gripper.

It should be understood that the process shown in FIG. 5 is merely exemplary. In actual application, one or more steps may be increased or decreased in the process shown in FIG. 5 according to requirements.

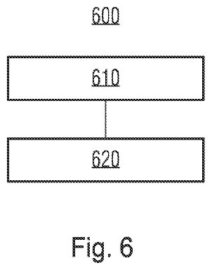

FIG. 6 is a schematic block diagram of an apparatus 600 for gripping a plurality of types of circuit boards incorporating teachings of the present disclosure. As shown in FIG. 6, the apparatus 600 may include at least one processor 610 and a memory 620. The memory 620 may be coupled to the at least one processor 610, and stores executable instructions. The executable instructions, when being executed by at least one processor 610, may implement a specific process of the method described with reference to FIG. 4 or FIG. 5. For the brevity of description, details are not described herein again.

In some embodiments, a computer program product may be tangibly stored on a computer-readable medium and include computer-executable instructions, the computer-executable instructions, when being executed, causing at least one processor to perform one or more of the processes described with reference to FIG. 4 and FIG. 5. All the operations in the methods described above are merely exemplary, and the present disclosure is not limited to any operation in the method or a sequence of the operations, but should cover all other equivalent transformations under the same or similar concept.

All the modules in the apparatus described above may be implemented in various manners. The modules may be implemented as hardware, software, or a combination thereof. In addition, any of the modules may be further functionally divided into sub-modules or combined together.

The processor has been described with reference to various apparatuses and methods. The processors may be implemented by using electronic hardware, computer software, or any combination thereof. Whether the processors are implemented as the hardware or the software depends on specific application and an overall design constraint imposed on the system. In an example, the processor, any part of the processor, or any combination of the processors provided in the present disclosure may be implemented as a microprocessor, a microcontroller, a digital signal processor (DSP), a field programmable gate array (FPGA), a programmable logic controller (PLC), a state machine, a gate logic, a discrete hardware circuit, and another suitable processing component configured to perform the functions described in this disclosure. Functions of the processor, any part of the processor, or any combination of the processors provided in the present disclosure may be implemented as software executed by a microprocessor, a microcontroller, a DSP, or another suitable platform.

The foregoing description is provided to cause that any person skilled in the art may implement the teachings described in this specification. Various modifications to these aspects are obvious to a person skilled in the art, and the general principles defined in this specification may be applied to other aspects. Therefore, the claims are not intended to be limited to the aspects shown in the specification. All structural and functional equivalent transformations to the elements of the aspects described in the present disclosure that are already known or about to be known to a person skilled in the art are clearly included in this specification by reference, and are intended to be covered by the claims.

A person skilled in the art should understand that various modifications and variations can be made to the embodiments disclosed above without departing from the essence of the present invention, and these modifications and variations shall fall within the protection scope of the present disclosure.

What is claimed is:

1. A method for gripping a plurality of types of circuit boards, the method comprising:
gripping a first circuit board using a first sub-gripper of an integrated mechanical gripper, wherein the integrated mechanical gripper comprises a plurality of sub-grippers;
placing the first circuit board into a transfer platform;
gripping the first circuit board from the transfer platform using a second sub-gripper of the plurality of sub-grippers, flipping the first circuit board, and placing the flipped first circuit board into a splitter;
splitting the first circuit board into at least one second circuit board with a different type or size from the first circuit board; and
gripping the second circuit board from the splitter using a third sub-gripper of the plurality of sub-grippers.

2. The method according to claim 1, wherein:
gripping the first circuit board comprises vertically gripping the first circuit board from at least one first material box using the first sub-gripper; and
flipping the first circuit board comprises flipping the first circuit board from a vertical placement to a horizontal placement.

3. The method according to claim 2, wherein:
the first circuit board comprises a complete circuit board;
the at least one first material box stores respectively complete circuit boards of different sizes;
each first material box stores at least one complete circuit board of the same size at fixed intervals using partition boards; and
a width between the partition boards is adjustable according to the size of the complete circuit board.

4. The method according to claim 2, wherein the at least one first material box is placed at a predetermined position.

5. The method according to claim 2, wherein vertically gripping the first circuit board from at least one first material box by using the first sub-gripper further comprises guiding the first sub-gripper to a corresponding first material box in a visual guidance manner, wherein the corresponding first material box stores circuit boards of the same size.

6. The method according to claim 1, further comprising
checking position accuracy of the first circuit board in the splitter using machine vision when the flipped first circuit board is placed into the splitter; and
if it is found that the position accuracy of the first circuit board in the splitter is lower than a threshold, adjusting a position of the first circuit board in the splitter based on the machine vision using the second sub-gripper.

7. The method according to claim 1, further comprising:
splitting the flipped first circuit board into at least one third circuit board in the splitter, wherein the third circuit board has a different type or size from the first circuit board and the second circuit board; and
gripping the third circuit board using a fourth sub-gripper of the plurality of sub-grippers, to place the third circuit board into a second material box.

8. The method according to claim 7, wherein:
the third circuit board comprises a scrap circuit board; and
the second material box is a scrap material box.

9. The method according to claim 1, wherein the second circuit board comprises a single circuit board, and
the method further comprises
transferring the single circuit board to a conveying belt at an unloading port using the third sub-gripper, to convey the single circuit board using the conveying belt.

10. The method according to claim 1, further comprising
transferring the first circuit board to a scanner for scanning b-y using the first sub-gripper before the first circuit board is placed into the transfer platform.

11. An integrated mechanical gripper for gripping a plurality of types of circuit boards, the gripper comprising:
a first sub-gripper configured to grip a first circuit board from a first material box and convey the gripped first circuit board to a transfer platform;
a second sub-gripper configured to grip the first circuit board at the transfer platform, flip the first circuit board, and place the flipped first circuit board into a splitter;
wherein the splitter splits the first circuit board into at least one second circuit board, wherein the second circuit board has a different type or size from the first circuit board; and
a third sub-gripper configured to grip the second circuit board at the splitter.

12. The integrated mechanical gripper according to claim 11, wherein:
gripping a first circuit board using the first sub-gripper comprises vertically gripping the first circuit board from at least one first material box using the first sub-gripper; and
flipping the first circuit board comprises flipping the first circuit board from a vertical placement to a horizontal placement.

13. The integrated mechanical gripper according to claim 12, wherein:
the first circuit board a complete circuit board; and
the at least one first material box is capable of respectively storing complete circuit boards of different sizes, each first material box stores at least one complete circuit board of the same size at fixed intervals by using partition boards, and a width between the partition boards is adjustable according to the size of the complete circuit board.

14. The integrated mechanical gripper according to claim 12, wherein vertically gripping the first circuit board from at least one first material box using the first sub-gripper further comprises: guiding the first sub-gripper to a corresponding first material box in a visual guidance manner, to grip the first circuit board, wherein the corresponding first material box stores circuit boards of the same size.

15. The integrated mechanical gripper according to claim 11, wherein the flipped first circuit board is further split into at least one third circuit board in the splitter, the third circuit board has a different type or size from the first circuit board and the second circuit board, and the integrated mechanical gripper further comprises:
a fourth sub-gripper configured to: grip the third circuit board, and place the third circuit board into a second material box;
wherein the third circuit board comprises a scrap circuit board; and
the second material box comprises a scrap material box.

16. The integrated mechanical gripper according to claim 11, wherein the second sub-gripper is further configured to,
when the flipped first circuit board is placed into the splitter, if it is found by using machine vision that position accuracy of the first circuit board in the splitter is lower than a threshold, adjust a position of the first circuit board in the splitter based on the machine vision.

17. The integrated mechanical gripper according to claim 11, wherein:
the second circuit board comprises a single circuit board, and
the third sub-gripper is further configured to transfer the single circuit board to a conveying belt at an unloading port, to convey the single circuit board by using the conveying belt.

18. The integrated mechanical gripper according to claim 11, wherein the first sub-gripper is further configured to transfer the first circuit board to a scanner for scanning before the gripped first circuit board is placed into the transfer platform.

19. An apparatus for gripping a plurality of types of circuit boards, the apparatus comprising:
a processor; and
a memory coupled to the processor and storing executable instructions;
wherein the executable instructions, when executed by the processor, cause the processor to
grip a first circuit board using a first sub-gripper of an integrated mechanical gripper, wherein the integrated mechanical gripper comprises a plurality of sub-grippers;
place the first circuit board into a transfer platform;
grip the first circuit board from the transfer platform using a second sub-gripper of the plurality of sub-grippers, flipping the first circuit board, and placing the flipped first circuit board into a splitter;
split the first circuit board into at least one second circuit board with a different type or size from the first circuit board; and
grip the second circuit from the splitter using a third sub-gripper of the plurality of sub-grippers.

20. A system for gripping a plurality of types of circuit boards, the system comprising:
a first material box configured to store a first circuit board;
a robot with an integrated mechanical gripper configured to grip, convey, and flip the first circuit board and grip and convey other circuit boards of different types or sizes;
a transfer platform configured to store the first circuit board conveyed from the integrated mechanical gripper; and
a splitter configured to obtain the flipped first circuit board from the integrated mechanical gripper and split the flipped first circuit board to obtain a second circuit board;
wherein
the integrated mechanical gripper comprises at least a first sub-gripper, a second sub-gripper, and a third sub-gripper;
the first sub-gripper is configured to grip the first circuit board from the first material box and convey the first circuit board to the transfer platform;
the second sub-gripper is configured to grip the first circuit board from the transfer platform, flip the first circuit board, and convey the flipped first circuit board to the splitter; and
the third sub-gripper is configured to grip the second circuit board from the splitter and convey the second circuit board.

21. The system according to claim 20, further comprising
a scrap material box configured to store a scrap circuit board;
wherein the scrap circuit board is obtained by splitting the first circuit board by the splitter; and
the integrated mechanical gripper further comprises a fourth sub-gripper configured to grip the scrap circuit board from the splitter and convey the scrap circuit board to the scrap material box.

22. The system according to claim 20, further comprising
a conveying belt configured to obtain the second circuit board from the third sub-gripper and convey the second circuit board.

23. The system according to claim 20, further comprising
a scanner configured to scan the first circuit board before the first circuit board is split.

24. (canceled)
